(19) United States
(12) Patent Application Publication
(10) Pub. No.: US 2019/0189734 A1
(43) Pub. Date: Jun. 20, 2019

(54) COUPLED T-COIL

(71) Applicant: Avago Technologies General IP (Singapore) Pte. Ltd., Singapore (SG)

(72) Inventors: Guansheng Li, Irvine, CA (US); Ullas Singh, Irvine, CA (US); Delong Cui, Irvine, CA (US); Jun Cao, Irvine, CA (US); Afshin Momtaz, Irvine, CA (US)

(21) Appl. No.: 15/849,435

(22) Filed: Dec. 20, 2017

(51) Int. Cl. H01L 49/02

(52) U.S. Cl. CPC H01L 28/10; H01L 28/60

(57) ABSTRACT

Systems and methods disclosed herein provide a coupled T-coil circuit for differential mode bandwidth extension and common mode rejection. The coupled T-coil circuit includes a first layer including at least a first portion of a first T-coil circuit and a first portion of a second T-coil circuit, and a second layer disposed on top of the first layer and interconnected to the first layer, the second layer including at least a second portion of the first T-coil circuit and a second portion of the second T-coil circuit. The first T-coil circuit includes one or more first coils with a first wind direction. The second T-coil circuit comprises one or more second coils with a second wind direction. The first wind direction can be opposite the second wind direction.

### TECHNICAL FIELD

The present disclosure relates generally to systems and methods for broadband signal processing. More particularly, the present disclosure relates to systems and methods utilizing coupled T-coil for differential mode bandwidth extension and common mode stability.

### BACKGROUND

Broadband buffers, amplifiers, and equalizers are widely used in high speed signal processing systems ranging from high-speed serializer/deserializers (SerDes) to high-speed analog-to-digital converters (ADC). Inductive peaking techniques, such as shunt peaking, series peaking, and T-coils are used to extend bandwidth of these buffers. Among these techniques, the T-coil is known to give the largest bandwidth extension, but use of T-coils is subject to several problems that can impact performance.

### BRIEF DESCRIPTION OF THE DRAWINGS

Various objects, aspects, features, and advantages of the disclosure will become more apparent and better understood by referring to the detailed description taken in conjunction with the accompanying drawings, in which like reference characters identify corresponding elements throughout. In the drawings, like reference numbers generally indicate identical, functionally similar, and/or structurally similar elements.

FIG. 1A depicts a diagram of a signal amplifying system utilizing one or more coupled T-coil circuits according to an illustrative embodiment;

FIG. 1B depicts an equivalent circuit schematic of a coupled T-coil circuit according to an illustrative embodiment;

FIG. 2 depicts a diagram of a coupled T-coil circuit according to an illustrative embodiment.

FIG. 3 depicts a diagram of a coupled T-coil integrated circuit according to an illustrative embodiment

FIG. 4 depicts a flow chart of a process of providing a coupled T-coil to extend differential mode bandwidth and improve common mode stability and common mode rejection according to an illustrative embodiment.

The details of various embodiments of the methods and systems are set forth in the accompanying drawings and the description below.

### DETAILED DESCRIPTION

Before turning to the figures, which illustrate the example embodiments in detail, it should be understood that the application is not limited to the details or methodology set forth in the description or illustrated in the figures. It should also be understood that the terminology is for the purpose of description only and should not be regarded as limiting.

T-coils have been used for extending bandwidth, but only in a single-ended way. Therefore, two stand-alone T-coils are usually used in differential pair to process differential signals. However, two stand-alone T-coils usually take large area and add to cost. Further, a broadband amplifier utilizing two stand-alone T-coils may have stability issues due to inductive loading and poor reverse isolation. The stability issue for a differential mode of T-coils can be improved by applying a neutralization capacitor to the T-coil circuit, but this neutralization capacitor increases (e.g., doubles) instability in a common mode of the T-coils. Stability can also be improved by using cascode, which gives better reverse isolation, but using cascode requires more voltage headroom and is not suitable for a scaled complementary metal-oxide-semiconductor (CMOS) process with a low supply voltage.

Referring generally to the figures, systems and methods for providing a coupled T-coil are described according to one or more illustrative embodiments. The coupled T-coil keeps the bandwidth extension capability of the conventional T-coils and improves common mode stability and common mode rejection. The coupled T-coil includes two T-coils configured to stack on top of each other, which saves significant area and cost compared to the conventional T-coils. Each T-coil in a coupled T-coil is smaller than a conventional stand-alone T-coil with same effective inductance, because mutual coupling increases the unit-length inductance of the coupled T-coil. An input impedance of the coupled T-coil is not inductive, due to inductance cancellation in common mode operation. In some implementations, the coupled T-coil embodiments of the present disclosure provide differential mode bandwidth extension and common mode stability.

One embodiment of the present disclosure relates to an integrated circuit including a coupled T-coil circuit. The coupled T-coil circuit includes a first layer including at least a first portion of a first T-coil circuit and a first portion of a second T-coil circuit, and a second layer disposed on top of the first layer and interconnected to the first layer, the second layer including at least a second portion of the first T-coil circuit and a second portion of the second T-coil circuit. The first T-coil circuit includes one or more first coils with a first wind direction. The second T-coil circuit comprises one or more second coils with a second wind direction. The first wind direction opposites the second wind direction.

Another embodiment of the present disclosure relates to a method for providing a coupled T-coil circuit. The method includes forming a first T-coil circuit including forming one or more first coils with a first coil wind direction; forming a second T-coil circuit including forming one or more second coils with a second coil wind direction. The first wind direction opposites the second wind direction. The method further includes coupling the first T-coil circuit with the second T-coil circuit by stacking the one or more first coils and the one or more second coils on top of each other.

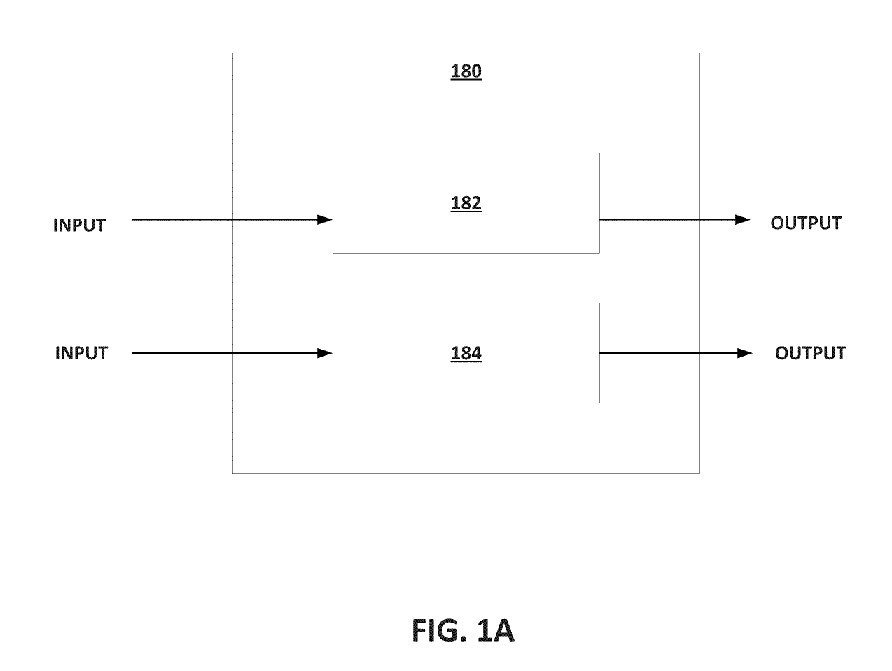

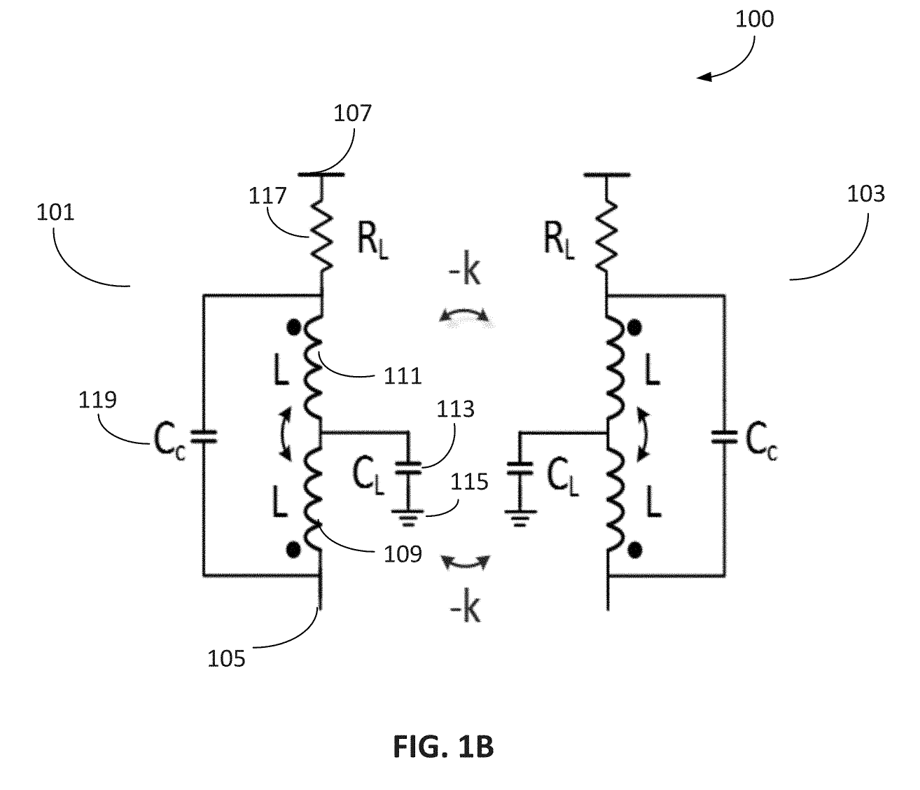

Referring to FIG. 1A, a diagram of a signal amplifying system 180 utilizing one or more coupled T-coil circuits is depicted according to an illustrative embodiment. In some embodiments, the signal amplifying system 180 is configured to amplify one or more input signals to generate output signals with desired bandwidth for high speed signal processing systems ranging from high-speed serializer/deserializers (SerDes) to high-speed analog-to-digital converters (ADC). For example, the signal amplifying system 180 may be used as a broadband buffer, an amplifier, and an equalizer. The signal amplifying system 180 is not limited to SerDes or ADC. The Signal amplifying system 180 may be used in any signal processing system.

The signal amplifying system 180 includes one or more coupled T-coil circuits (e.g., coupled T-coil 182, and coupled T-coil 184). Each T-coil circuit is configured to provide differential mode bandwidth extension and common mode rejection for input signals. Each coupled T-coil circuit includes a first layer including at least a first portion of a first T-coil circuit and a first portion of a second T-coil circuit, and a second layer disposed on top of the first layer and interconnected to the first layer, the second layer including at least a second portion of the first T-coil circuit and a second portion of the second T-coil circuit. The first T-coil circuit includes one or more first coils with a first wind direction. The second T-coil circuit comprises one or more second coils with a second wind direction. The first wind direction is opposite the second wind direction.

Referring to FIG. 1B, an equivalent circuit schematic of a coupled T-coil circuit 100 is depicted according to an illustrative embodiment. The coupled T-coil circuit 100 includes two T-coil circuits 101 and 103 arranged to stack on each other in order to achieve a higher coupling coefficient K between the two T-coils. In some embodiments, the T-coil circuit 101 is same as the T-coil circuit 103. In some embodiments, the T-coil circuit 101 may be different from the T-coil circuit 103. In some embodiments, the T-coil circuit 101 and the T-coil circuit 103 are arranged symmetrically to each other.

While various paragraphs below reference T-coil circuits 101 and 103 as having particular discrete components, it should be understood that, in some instances, the T-coil circuits 101 and 103 do not include the discrete components themselves, but rather an equivalent circuit of the T-coil circuits 101 and 103 includes the components (i.e., the T-coil circuits 101 and 103 are structured to behave similarly to a circuit composed of the indicated discrete components). Each of the T-coil circuits 101 and 103 includes an input terminal 105 and an output terminal 107. The T-coil circuit 101 includes a first inductor portion 109 and a second inductor portion 111 connected between the input terminal 105 and a resistor 117 that is connected to the output terminal 107. The first inductor portion 109 and the second inductor portion 111 have same inductance L as shown in FIG. 1B according to some embodiments. The first inductor portion 109 and the second inductor portion 111 have different inductances according to some other embodiments. A first end of a capacitor 113 is connected between the first inductor portion 109 and the second inductor portion 111. A second end of the capacitor 113 is connected to ground 115. In some embodiments, the capacitor 113 is used for load control. For example, when there is a sudden voltage/current spike, which can damage the T-coil circuit, the T-coil circuit can route excess voltage/current to the capacitor 113.

The T-coil circuit 107 further includes a capacitor 119 connected in parallel to the inductor portions 109 and 111. The capacitor 119 includes a first end connected between the second inductor portion 111 and the resistor 117, and a second end connected between the first inductor portion 109 and the input terminal 105. The capacitor 119 provides capacitance to the inductor portions 109 and 111. The capacitor 119 is disposed in parallel to the inductor portions 109 and 111.

The T-coil circuit 101 and the T-coil circuit 103 are symmetrically arranged to stack on each other according to some embodiments. The inductor portions of the T-coil circuit 101 are stacked over the inductor portions of the T-coil circuit 103. In this way, a desired inductive coupling coefficient K is generated between the proximate coupled inductor portions. In some embodiments, the inductive coupling coefficient K has a value between −1 and 1.

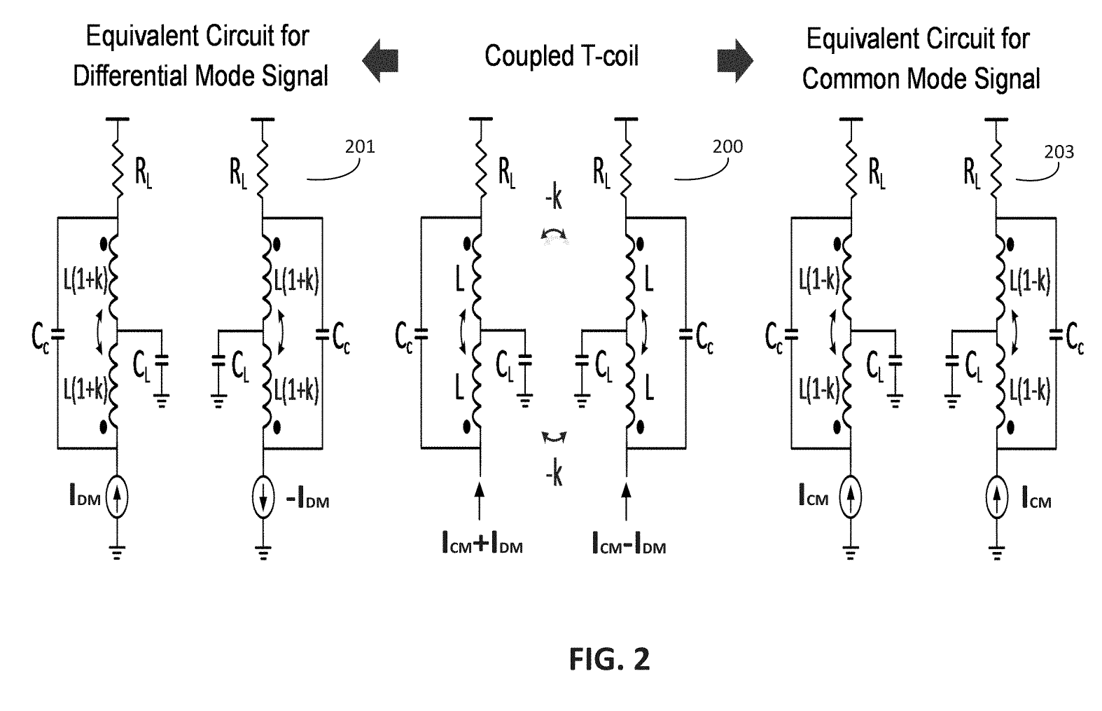

Referring to FIG. 2, a diagram of a coupled T-coil circuit 200 is depicted according to an illustrative embodiment. The coupled T-coil circuit 200 is similar to the circuit 100 as described in FIG. 1B. The coupled T-coil circuit has an input current I_{CM}+I_{DM} at an input terminal of a first T-coil circuit of the coupled T-coil circuit, and an input current I_{CM}−I_{DM} at an input terminal of a second T-coil circuit of the coupled T-coil circuit. The I_{CM} is a common mode component of the input current. The I_{DM} is a differential mode component of the input current.

When considering the common mode component I_{CM} of the input current, the coupled T-coil circuit 200 is equivalent to a coupled T-coil circuit 203 for common mode signal I_{CM}. As shown in the coupled T-coil circuit 203, the common mode signals have same directions as input signals. These same-direction common mode signals are input to both T-coil circuits of the coupled T-coil circuit 203.

The coupled T-coil circuit 203 includes two T-coil circuits symmetrically coupled together, so that the coil directions are opposite to each other. In some embodiments, each of the T-coil circuits of the coupled T-coil circuit 203 has a different coil winding direction. For example, the first T-coil circuit has a clockwise coil design and the second T-coil circuit has a counterclockwise coil design, so that the current input to the first T-coil circuit flows in a clockwise direction and the current input to the second T-coil circuit flows in a counterclockwise direction. The first T-coil circuit generates a first magnetic field using the clockwise current flow. The second T-coil circuit generates a second magnetic field using the counterclockwise current flow. The first magnetic field and the second magnetic field have opposite directions. In this way, the magnetic fields generated by the T-coil circuit of the coupled T-coil circuit 203 are canceled by each other for common mode input signals.

The two T-coil circuits of the coupled T-coil circuit 203 are stacked at each other proximately, so that a desired inductive coupling coefficient K can be generated. The inductive coupling coefficient K is generally between −1 and 1. The inductance for a coil input with common mode signals and under coupling effect is calculated by L(1−K). Thus, the larger the inductive coupling coefficient is, the lower the inductance for the coil is. In order to reduce or eliminate the effect of common mode inductance and improve common mode stability and common mode rejection, the coupled T-coil 203 is structured to generate a larger inductive coupling coefficient, which is closer to 1 to cancel the magnetic field generated by the common mode and generate smaller and low-Q effective inductance for common mode signals. In some embodiments, the inductive coupling coefficient may be equal to 0.5. In some embodiments, the inductive coupling coefficient is determined in part according to proximity and alignment between the two T-coil circuits of the coupled T-coil circuit. For example, in some embodiments, the K value can be modified by changing a lateral distance between the two layers/circuits of the coupled T-coil circuit 203. In some embodiments, the lateral distance between the layers may be between 0.5 micrometers and 1.1 micrometers (e.g., approximately 0.8 micrometers). In some embodiments, the K value can be modified by modifying an alignment between the T-coil circuits/layers. For example, for T-coil circuits with a thickness of 4 micrometers, in some implementations, misaligning the layers/circuits by 2 to 4 micrometers may result in a reduction of K of approximately 0.1 to 0.2.

When considering the differential mode signal I_{DM} of the input current, the coupled T-coil circuit 200 is equivalent to a coupled T-coil circuit 201 for differential mode signal I_{DM}. As shown in the coupled T-coil circuit 201, the differential mode signals have opposite directions as input signals. These opposite-direction differential mode signals are input to both T-coil circuits of the coupled T-coil circuit 201.

The coupled T-coil circuit 201 has the same configuration as the coupled T-coil circuit 203. In the same way as T-coil circuit 203, each of the T-coil circuit of the coupled T-coil circuit 201 has different coil wind directions. For example, the first T-coil circuit has a clockwise coil design and the second T-coil circuit has a counterclockwise coil design, so that the positive current input to the first T-coil circuit flows in a clockwise direction and the negative current input to the second T-coil circuit also flows in the clockwise direction. The first T-coil circuit generates a first magnetic field using the clockwise current flow. The second T-coil circuit generates a second magnetic field using the clockwise current flow. The first magnetic field and the second magnetic field have same directions. In this way, the magnetic fields generated by the T-coil circuit of the coupled T-coil circuit 201 are doubled in magnitude.

The two T-coil circuits of the coupled T-coil circuit 201 are stacked at each other proximately, so that a desired inductive coupling coefficient K can be generated. The inductive coupling coefficient K is generally between −1 and 1. The inductance for a coil input with common mode signals and under coupling effect is calculated by L(1+K) because the different-direction input. Thus, the larger the inductive coupling coefficient is, the higher the inductance for the coil is. In order to provide mutual coupling and enhance differential mode bandwidth extension, the coupled T-coil 201 is configured to generate a larger inductive coupling coefficient K, which is closer to 1 to enhance the magnetic field generated by the differential mode and generate larger inductance for differential mode signals.

As described with respect to both equivalent circuit 201 and equivalent circuit 203, the coupled T-coil circuit 200 is advantageously designed to differentiate bandwidth extension effect for differential mode signals and common mode signals. Compared to the conventional stand-alone T-coil circuits, the coupled T-coil circuit uses a smaller coils to provide same differential mode bandwidth extension, because the unit-length inductance of the coupled T-coil is increased by L(1+K). The coupled T-coil circuit also eliminates the inductive effect of the common mode signals by cancelling the magnetic field generated by common mode signals, which further improves the circuit stability. The coupled T-coil circuit reduces inductance for common mode signals by L(1−K), so that the common mode signals do not get much peaking, and get rejected at high frequency. The coupled T-coil lowers improves circuit performance for bandwidth extension and reduces cost due to area saving.

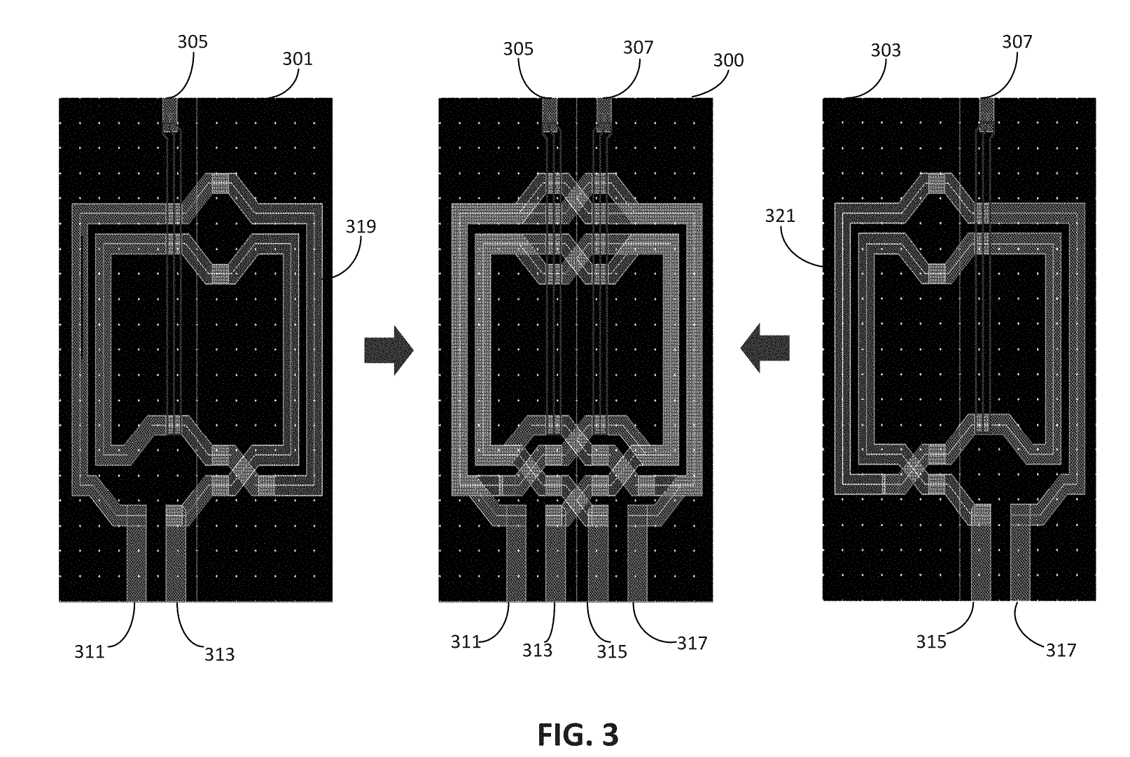

Referring to FIG. 3, a diagram of a coupled T-coil integrated circuit 300 is depicted according to an illustrative embodiment. The coupled T-coil integrated circuit 300 includes a first T-coil circuit 301 and a second T-coil circuit 303 stacked on top of each other. In some embodiments, each of the T-coil circuits 301 and 303 has at least a portion of the circuit formed in two interconnect layers of the integrate circuit 300. In some embodiments, the T-coil circuit 301 is formed similarly as the T-coil circuit 303, but printed on the integrated circuit (e.g., on a printed circuit board) in a symmetrical direction as shown in FIG. 3.

The first T-coil circuit 301 includes an input terminal 311 and an output terminal 313. In some embodiments, the input terminal 311 and the output terminal 313 can be exchanged for either input and output signals. The first T-coil circuit 301 includes a capacitor 305 similar as the capacitor 113 in FIG. 1B for load control.

The second T-coil circuit 303 includes an input terminal 317 and an output terminal 315. In some embodiments, the input terminal 315 and the output terminal 317 can be exchanged for either input and output signals. The second T-coil circuit 303 includes a capacitor 307 similar as the capacitor 113 in FIG. 1B for load control.

In some embodiments, the first and the second T-coil circuits 301 and 303 have a same coil size so that when two circuits are coupled, the two circuits are completely interleaved. This coupled T-coil structure saves significant area, which further reduces cost. In addition, this coupled T-coil structure provides mutual coupling of the two T-coil circuits for differential mode signals, improves stability by cancelling common mode inductive effect, and improves common mode rejection by reducing inductance for the commode signals.

For common mode signals, which have same magnitude and same direction, the first T-coil circuit 301 receives a common mode signal at the input terminal 311 and the second T-coil circuit 303 receives a common mode signal at the input terminal 317. Within the first T-coil circuit 301, the common mode signal flows along with the coil 319 to the output terminal 313 and forms a clockwise current flow. Within the second T-coil circuit 303, the common mode signal flows along T-coil circuit 321 to the output terminal 315 and forms a counterclockwise current flow. The clockwise current flow within the first T-coil circuit 301 generates a first magnetic field, and the counterclockwise current flow within the second T-coil circuit 303 generates a second magnetic field. The first and the second magnetic fields have same magnitude and opposite directions. Thus, the first and the second magnetic fields cancel each other. In this way, for common mode signals, the coupled T-coil circuit 300 is not inductive due to the induction cancellation, which improves circuit stability.

In addition, when the two T-coil circuits 301 and 303 are coupled proximately, an inductive coupling coefficient is increased. The inductance for common mode signals is inversely proportional to the inductive coupling coefficient. When the inductive coupling coefficient is increased, the inductance for the common mod signals is decreased, so that the common mode signals do not get much peaking and get rejected at high frequency. In this way, the coupled T-coil circuit 300 improves common mode rejection.

For differential mode signals, the first T-coil circuit 301 receives a first differential mode signal at the input terminal 311 and the second T-coil circuit 303 receives a second differential mode signal at the input terminal 317. The first and the second differential mode signals have same magnitude and opposite directions. For example, the first differential mode signal has a positive direction which flows from the input terminal 311 along the coil 319 to the output terminal 313. The second differential mode signal has a negative direction which flows from the output terminal 315 along the coil 321 to the input terminal 317. The first differential mode signal forms a clockwise current flow within the first T-coil circuit 301. The second differential mode signal also forms a clockwise current flow within the second T-coil circuit 303. The first T-coil circuit 301 generates a first magnetic field using the clockwise current flow. The second T-coil circuit 303 generates a second magnetic field using the clockwise current flow. The first and the second magnetic fields have same direction and same magnitude. When the first T-coil circuit 301 is coupled to the second T-coil circuit 303 to form the coupled T-coil circuit 300, the two T-coil circuits provides mutual coupling, which adds the first magnetic field and the second magnetic field together to form a doubled magnetic field. In this way, the coupled T-coil circuit 300 provides large bandwidth extension for differential mode signals.

In addition, the inductance for differential mode signals is directly proportional to the inductive coupling coefficient. When the inductive coupling coefficient is increased, the inductance for the differential mod signals is increased, so that the differential mode signals can be extended at a same level as conventional T-coils, but using much smaller coils. In this way, the coupled T-coil circuit 300 reduces both area and cost.

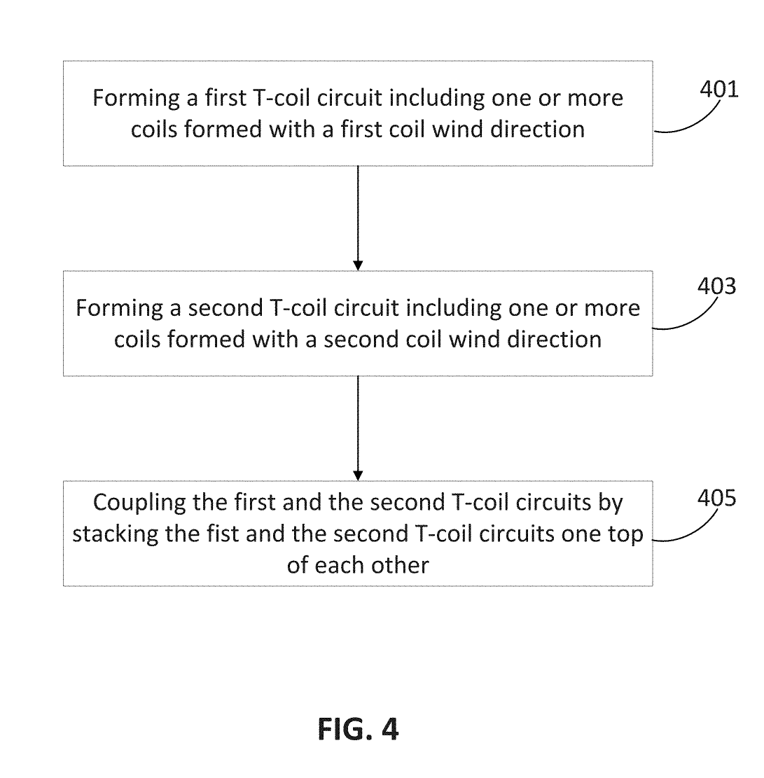

Referring to FIG. 4, a flow chart of a process 400 of providing a coupled T-coil to extend differential mode bandwidth and improve common mode stability and common mode rejection. At operation 401, forming the first T-coil circuit includes forming a first input terminal and a first output terminal and one or more first coils connected between the first input terminal and the first output terminal. The one or more first coils are formed in a first wind direction (e.g., clockwise or counterclockwise). The first input terminal and the first output terminal are configured to receive and output signals. The input signals include both differential mode signals and common mode signals. The one or more first coils are formed so that input signals form a current flow at a first flow direction within the one or more first coils and generates a first magnetic field.

In some embodiments, the first T-coil circuit is formed such that an equivalent circuit of the first T-coil circuit includes a first capacitor connected between the one or more first coils. The first capacitor is configured to receive excess voltage/current load. For example, when there is a sudden voltage/current spike, which may damage the first T-coil circuit, the first T-coil circuit may route excess voltage/current to the first capacitor. In some embodiments, the first T-coil circuit is formed such that an equivalent circuit of the first T-coil circuit includes a second capacitor connected between the input terminal and the output terminal and bypassing the one or more first coils.

At operation 403, forming the second T-coil circuit includes forming a second input terminal and a second output terminal, and one or more second coils connected between the second input terminal and the second output terminal. The one or more second coils are formed in a second wind direction (e.g., clockwise or counterclockwise). The second wind direction is different from the first wind direction of the one or more first coils. For example, if the one or more first coils are formed in a clockwise wind direction, the one or more second coils are formed in a counterclockwise wind direction, and vice versa.

The second input terminal and the second output terminal are configured to receive and output signals. The input signals include both differential mode signals and common mode signals. The one or more second coils are formed so that the input signals form a second current flow in a second flow direction within the one or more second coils and generates a second magnetic field. Because the one or more first coils and the one or more second coils have opposite wind directions, when the first T-coil circuit and the second T-coil circuit input signals with same direction (i.e., common mode signals), the first coils and the second coils have current flows in different directions, which further generates magnetic fields in opposite directions. In this way, when common mode signals are input to the first T-coil circuit and the second T-coil circuit, the magnetic fields generated by the first and the second T-coil circuits have same magnitude and opposite directions, which cancels the magnetic fields when the first and the second T-coil circuits stacked on top of each other. In some embodiments, the second T-coil circuit is formed similarly to the first T-coil circuit except with opposite coil wind directions.

At operation 405, the first T-coil circuit is coupled with the second T-coil circuit such that the first magnetic field generated by the first T-coil circuit overlaps the second magnetic field generated by the second T-coil circuit. In some embodiments, coupling the first and the second T-coil circuits includes: forming a first portion of the first T-coil circuit in a first interconnect layer, forming a first portion of the second T-coil circuit in parallel with the first portion of the first T-coil circuit in the first interconnect layer, forming a second portion of the T-coil circuit in a second interconnect layer, and forming a second portion of the second T-coil circuit in parallel with the second portion of the first T-coil circuit in the second interconnect layer. The first and the second interconnect layers are interconnected and stacked together vertically. The structure of the coupled T-coil circuit allows common mode signals flow in different directions within the first T-coil circuit and the second T-coil circuit, so that the magnetic fields generated by the different direction current flows get cancelled. In this way, the coupled T-coil circuit in not inductive for common mode signals. The structure of the coupled T-coil circuit further allows differential mode signals flow in a same direction within the first T-coil circuit and the second T-coil circuit, so that the magnetic fields by the same direction current flows enhance each other to generate a larger magnetic field. In this way, the coupled T-coil circuit provides desired effective inductance for bandwidth extension.

In some embodiments, the first and the second T-coil circuits are coupled such that an inductive coupling coefficient between the first T-coil circuit and the second T-coil circuit reach a desired value. In some embodiments, increasing the inductive coupling coefficient lowers inductance of each coil of the coupled T-coil circuit for common mode signals, and increases inductance of each coil of the coupled T-coil circuit for differential mode signals. Because of the increased inductance of the coils of the coupled T-coil circuit, smaller coils are needed for providing desired bandwidth extension compared to conventional T-coil circuit.

The present disclosure has been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed invention. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention. One of average skill in the art will also recognize that the functional building blocks, and other illustrative blocks, modules and components herein, can be implemented as illustrated or by discrete components, application specific integrated circuits, processors executing appropriate software and the like or any combination thereof.

The present disclosure may have also been described, at least in part, in terms of one or more embodiments. An embodiment of the present invention is used herein to illustrate the present invention, an aspect thereof, a feature thereof, a concept thereof, and/or an example thereof. A physical embodiment of an apparatus, an article of manufacture, a machine, and/or a process that embodies the present invention may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

It should be noted that certain passages of this disclosure can reference terms such as “first” and “second” in connection with devices for purposes of identifying or differentiating one from another or from others. These terms are not intended to merely relate entities (e.g., a first coil and a second coil) temporally or according to a sequence, although in some cases, these entities can include such a relationship. Nor do these terms limit the number of possible entities (e.g., coils) that can operate within a system or environment.

It should be understood that the systems described above can provide multiple ones of any or each of those components and these components can be provided on either an integrated circuit or, in some embodiments, on multiple circuits, circuit boards or discrete components. In addition, the systems and methods described above can be adjusted for various system parameters and design criteria, such as number of coils, shape of coils, coil layers, etc. Although shown in the drawings with certain components directly coupled to each other, direct coupling is not shown in a limiting fashion and is exemplarily shown. Alternative embodiments include circuits with indirect coupling between the components shown.

It should be noted that although the flowcharts provided herein show a specific order of method steps, it is understood that the order of these steps can differ from what is depicted. Also two or more steps can be performed concurrently or with partial concurrence. Such variation will depend on the software and hardware systems chosen and on designer choice. It is understood that all such variations are within the scope of the disclosure.

While the foregoing written description of the methods and systems enables one of ordinary skill to make and use various embodiments of these methods and systems, those of ordinary skill will understand and appreciate the existence of variations, combinations, and equivalents of the specific embodiment, method, and examples herein. The present methods and systems should therefore not be limited by the above described embodiments, methods, and examples, but by all embodiments and methods within the scope and spirit of the disclosure.

1. An integrated circuit including a coupled T-coil circuit, the integrated circuit comprising:
a first layer comprising a first portion of a first T-coil circuit and a first portion of a second T-coil circuit; and
a second layer disposed on top of the first layer and interconnected to the first layer, the second layer including a second portion of the first T-coil circuit and a second portion of the second T-coil circuit, wherein the first T-coil circuit comprises one or more first coils with a first wind direction and the second T-coil circuit comprises one or more second coils with a second wind direction opposite the first wind direction.

2. The integrated circuit of claim 1, wherein an equivalent circuit of the first T-coil circuit comprises a first capacitor connected between the one or more first coils and ground.

3. The integrated circuit of claim 2, wherein the equivalent circuit of the first T-coil circuit comprises a second capacitor connected in parallel to the one or more first coils within the first T-coil circuit.

4. The integrated circuit of claim 1, wherein an equivalent circuit of the second T-coil circuit comprises a first capacitor connected between the one or more second coils and ground.

5. The integrated circuit of claim 4, wherein the equivalent circuit of the second T-coil circuit comprises a second capacitor connected in parallel to the one or more second coils within the second T-coil circuit.

6. The integrated circuit of claim 1, wherein the first T-coil circuit is configured to generate a first magnetic field for common mode signals.

7. The integrated circuit of claim 6, wherein the second T-coil circuit is configured to generate a second magnetic field for the common mode signals having an opposite direction of the first magnetic field.

8. The integrated circuit of claim 7, wherein the first and the second magnetic fields generated by the common mode signals have a same magnitude.

9. The integrated circuit of claim 1, wherein the coupled T-coil circuit is not inductive for common mode signals.

10. The integrated circuit of claim 1, wherein the first T-coil circuit is configured to generate a first magnetic field for differential mode signals.

11. The integrated circuit of claim 10, wherein the second T-coil circuit is configured to generate a second magnetic field for the differential mode signals.

12. The integrated circuit of claim 11, wherein the first and the second magnetic fields generated by the differential mode signals have same magnitude and same direction.

13-20. (canceled)

21. A system for amplifying signal, comprising:
an integrated circuit including a coupled T-coil circuit, the integrated circuit comprising:
a first layer comprising a first portion of a first T-coil circuit and a first portion of a second T-coil circuit; and
a second layer disposed on top of the first layer and interconnected to the first layer, the second layer including a second portion of the first T-coil circuit and a second portion of the second T-coil circuit, wherein the first T-coil circuit comprises one or more first coils with a first wind direction and the second T-coil circuit comprises one or more second coils with a second wind direction opposite the first wind direction.

22. The system of claim 21, wherein an equivalent circuit of the first T-coil circuit comprises a first capacitor connected between the one or more first coils and ground.

23. The system of claim 22, wherein the equivalent circuit of the first T-coil circuit comprises a second capacitor connected in parallel to the one or more first coils within the first T-coil circuit.

24. The system of claim 21, wherein an equivalent circuit of the second T-coil circuit comprises a first capacitor connected between the one or more second coils and ground.

25. The system of claim 24, wherein the equivalent circuit of the second T-coil circuit comprises a second capacitor connected in parallel to the one or more second coils within the second T-coil circuit.

26. The system of claim 21, wherein the first T-coil circuit is configured to generate a first magnetic field for common mode signals.

27. The system of claim 26, wherein the second T-coil circuit is configured to generate a second magnetic field for the common mode signals having an opposite direction of the first magnetic field.

28. The system of claim 27, wherein the first and the second magnetic fields generated by the common mode signals have a same magnitude.
